(19) United States
(12) Patent Application Publication
(10) Pub. No.: US 2011/0308607 A1
(43) Pub. Date: Dec. 22, 2011

(54) GROUP III-V SOLAR CELL AND METHOD OF MANUFACTURING THE SAME

(75) Inventors: YEE-SHYI CHANG, TAIPEI (TW); Chi-Jen Liu, Taipei (TW)

(73) Assignee: AN CHING NEW ENERGY MACHINERY & EQUIPMENT CO.,LTD., TAIPEI (TW)

(21) Appl. No.: 13/017,221

(22) Filed: Jan. 31, 2011

(30) Foreign Application Priority Data
Jun. 18, 2010 (TW) 99119947

(51) Int. Cl. H01L 31/0376; H01L 31/0352

(52) U.S. Cl. 136/258; 438/94; 257/E31.032

(57) ABSTRACT

A Group III-V solar cell and a manufacturing method thereof, wherein, three amorphous silicon layers are formed on a substrate, which includes a first type amorphous silicon layer, an intrinsic amorphous silicon layer, and a second type amorphous silicon layer. The lattice characteristics of amorphous silicon layer are utilized, and a Group III-V polycrystalline semiconductor layer is formed on said amorphous silicon layer, such that amorphous silicon and Group III-V material are able to perform photoelectric conversion simultaneously in raising photoelectric conversion efficiency of said Group III-V solar cell effectively by means of a direct energy gap of said Group III-V material.

### BACKGROUND OF THE INVENTION

1. Field of the Invention

The present invention relates to a solar cell and a method of manufacturing the same, and in particular to a Group III-V solar cell and a method of manufacturing the same, which is capable of performing simultaneous photoelectric conversions by utilizing amorphous silicon and Group III-V materials.

2. The Prior Arts

With the advent of the age of high oil price and worldwide concern about global warming and environment protection, the green energy industry is thus stimulated to develop and progress rapidly. Presently, its related revenue worldwide has reached as high as several billion US dollars annually. The green energy is also referred to as a clean energy (including water resources, solar energy, wind energy, geothermal energy, and clean coal energy, etc.), and that includes almost all the environment friendly energy resources. Moreover, with the worldwide emphasis on energy conservation and carbon reduction, solar energy provided by solar cell is considered as a promising alternative and replacement for the fast depleting and exhausting oil resources. In general, solar cell has the advantage of convenient in usage, non-exhaustible, pollution free, noise immunity, no rotational parts required, long service life, size adjustable, and easy incorporation into ordinary buildings. For many parts of the world, by way of example, for most parts in Taiwan, sunlight irradiation is quite sufficient, thus it is suitable for developing and promoting solar cell electricity generation and the solar energy industry.

However, presently, the solar cell electricity generation is not quite popularized and widely utilized, the main reason for this is that, its price is rather high and beyond the reach of ordinary households. In addition to its high cost of manufacturing, its photoelectric conversion efficiency is rather low, thus leading to its overly long period of cost recovery. For an ordinary solar cell presently on the market, its photoelectric conversion efficiency is as low as 15%˜18%, for some of the so-called high efficiency solar cell, it photoelectric conversion efficiency is alleged to be able to reach above 22%. Nevertheless, its overall efficiency is still rather low.

Though presently on the market, quite a few solar cells are capable of achieving higher photoelectric conversion efficiency, yet, since they utilize special material and technology to produce, thus leading to high production cost and long cost recovery time. Therefore, how to increase the photoelectric conversion efficiency of a solar cell, while controlling its production cost properly, is a most important task in this field.

### SUMMARY OF THE INVENTION

In view of the problems and shortcomings of the prior art, the present invention provides a Group III-V solar cell and a method of manufacturing the same, so as to overcome the problems and deficiency of the prior art.

A major objective of the present invention is to provide a Group III-V solar cell and a method of manufacturing the same, wherein, the amorphous silicon and Group III-V materials are used to perform photoelectric conversion simultaneously, so as to raise and enhance the photoelectric conversion efficiency of the solar cell, and solve the problem and deficiency of the prior art.

In order to achieve the above mentioned objective, the present invention provides a Group III-V solar cell, comprising: a substrate, a first type amorphous silicon layer, an intrinsic amorphous silicon layer, a second type amorphous silicon layer, and a Group III-V polycrystalline semiconductor layer. Wherein, the lattice characteristics of the amorphous silicon layer are utilized, and the Group III-V polycrystalline semiconductor layer is placed on the amorphous silicon layer, such that the amorphous silicon and the Group III-V material are able to perform photoelectric conversion simultaneously in raising the photoelectric conversion efficiency of a solar cell by means of the direct energy gap of the Group III-V material.

In addition, the present invention provides a Group III-V solar cell manufacturing method, comprising the following steps: firstly, providing a glass substrate; next, through utilizing Plasma Enhanced Chemical Vapor Deposition (PECVD), depositing a first type amorphous silicon layer on the glass substrate, forming an intrinsic amorphous silicon layer on the first type amorphous silicon layer, and forming a second type amorphous silicon layer on the intrinsic amorphous silicon layer; then depositing a Group III-V polycrystalline semiconductor layer on the second type amorphous silicon layer by means of a Metal-Organic Chemical Vapor Deposition (MOCVD). In the present invention, the lattice characteristics of amorphous silicon layer are used, and the Group III-V polycrystalline semiconductor layer is placed on the amorphous silicon layer, such that the amorphous silicon and the Group III-V material are able to perform photoelectric conversion simultaneously in raising the photoelectric conversion efficiency of a solar cell by means of the direct energy gap of the Group III-V material. In addition, the production cost of solar cell can be properly controlled, so that its cost recovery period is shortened, thus further raising it competitiveness on the market.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions.

### BRIEF DESCRIPTION OF THE DRAWINGS

The related drawings in connection with the detailed descriptions of the present invention to be made later are described briefly as follows, in which:

FIG. 1 is a schematic diagram of a Group III-V solar cell according to the present invention;

FIG. 2 is a flowchart of the steps of a method of manufacturing a Group III-V solar cell according to the present invention; and

FIGS. 3A˜3E are schematic diagrams respectively of structures of Group III-V solar cell corresponding to various steps of manufacturing a Group III-Vsolar cell according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

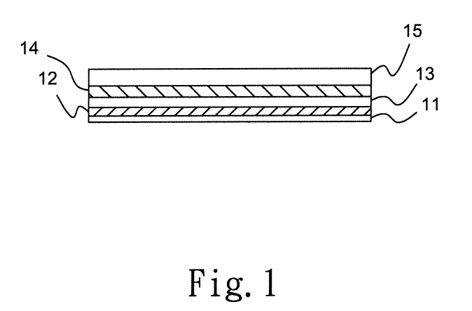

Firstly, refer to FIG. 1 for a schematic diagram of a Group III-V solar cell according to the present invention. As shown in FIG. 1, the Group III-V solar cell of the present invention comprises: a substrate 11, a first type amorphous silicon layer 12, an intrinsic amorphous silicon layer 13, a second type amorphous silicon layer 14, and a Group III-V polycrystalline semiconductor layer 15. Wherein, the substrate 11 can be made of glass, quartz, transparent plastic, sapphire, or flexible materials.

In order to receive sunlight and generate electricity, P-type semiconductor and N-type semiconductor (the first type amorphous silicon layer 12, and the second type amorphous silicon layer 14) of different conductive properties are applied on two sides of an intrinsic amorphous silicon layer 13, such that when sunlight irradiates on the PN junction, part of the electrons will leave the atom to become free electrons for having sufficient energy, and holes are created for the lost electrons. Then the P-type semiconductor and N-type semiconductor will attract the holes and electrons respectively in separating the positive charges and the negative charges, hereby producing potential difference on two opposite sides of the PN junction. Then, the conduction layer is connected to a circuit, so that the electrons can flow through and recombine with holes on the other side of the PN junction, thus producing a current in the circuit for outputting electrical energy to outside through a lead wire.

As mentioned above, the first type amorphous silicon layer 12, and the second type amorphous silicon layer 14 can be a P-type semiconductor or an N-type semiconductor respectively. In other words, in case that the first type amorphous silicon layer 12 is a P-type semiconductor, then the second type amorphous silicon layer 14 is an N-type semiconductor. On the other hand, in case that the first type amorphous silicon layer 12 is an N-type semiconductor, then the second type amorphous silicon layer 14 is a P-type semiconductor. Wherein, P-type semiconductor can be made of a transparent conductive oxide selected from a group consisting of: copper aluminum oxide, copper gallium oxide, copper scandium oxide, copper chromium oxide, copper indium oxide, copper yttrium oxide, and silver indium oxide etc.; while N-type semiconductor can be made of a transparent conductive oxide selected from a group consisting of: zinc oxide, tin oxide, indium zinc oxide, and indium tin oxide, etc.

The operation principle of a Group III-V polycrystalline semiconductor layer 15 is the same as that of the amorphous silicon layer mentioned above, however, the ordinary silicon crystal material is only able to absorb sunlight in a range of 400˜1100 nm of the spectrum; while a Group III-V polycrystalline semiconductor layer 15 is able to absorb sunlight of wider range of spectrum through multi junction compound semiconductor, hereby raising the photoelectric conversion efficiency of a solar cell significantly. For example, a triple junction concentrator type solar cell is able to absorb sunlight in a range of 300˜1900 nm of the spectrum. In addition to being a multi-junction structure, a Group III-V polycrystalline semiconductor layer 15 can also be a single junction structure. Wherein, Group III-V polycrystalline semiconductor layer 15 of a single junction structure may contain a P-type semiconductor and an N-type semiconductor; while a Group III-V polycrystalline semiconductor layer 15 of a multi junction structure may contain a P-type semiconductor, an intrinsic semiconductor, and an N-type semiconductor. The material of Group III-V polycrystalline semiconductor layer 15 can be selected from a group consisting of: GaAs, GaP, InP, AlGaAs, GaInAs, AlGaP, GaInP, AlGaAsP, InGaAsP, AlGaInAsP, or their combinations; or, alternatively, it can be selected from a group consisting of: GaN, InN, GaAl, AlGaN, AIInN, AIInGaN, or their combinations.

Therefore, for a Group III-V solar cell, in addition to producing electrical energy by means of first type amorphous silicon layer 12, the intrinsic amorphous silicon layer 13, and the second type amorphous silicon layer 14, the Group III-V polycrystalline semiconductor layer 15 is itself provided with a direct energy gap. Therefore, through the photoelectric conversions performed by amorphous silicon and Group III-V materials at the same time, the photoelectric conversion efficiency of a Group III-V solar cell can be raised effectively.

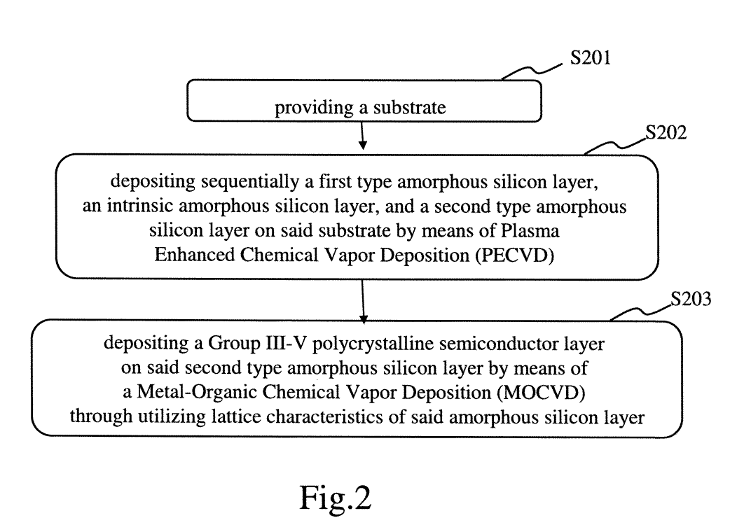

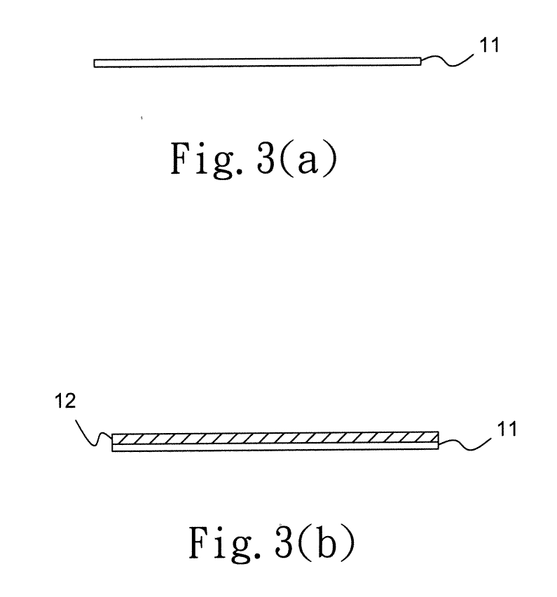

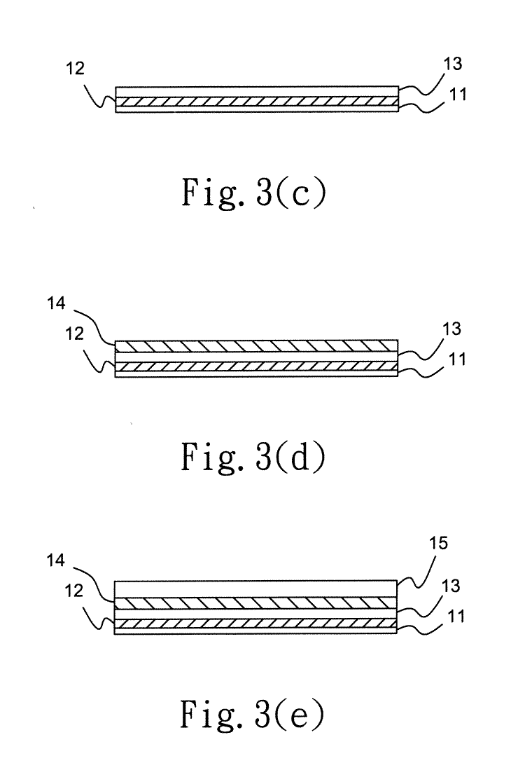

Subsequently, refer to FIG. 2 for a flowchart of the steps of a method of manufacturing a Group III-V solar cell according to the present invention. Also, refer to FIGS. 3A˜3E for schematic diagrams respectively of structures of Group III-V solar cell corresponding to various steps of manufacturing a Group III-V solar cell according to the present invention.

As shown in FIG. 2, the present invention provides a method of manufacturing a Group III-V solar cell, comprising the following steps: firstly, as shown in step S201, preparing a substrate 11 (as shown in FIG. 3A); next, as shown in step S202, depositing a first type amorphous silicon layer 12 on the glass substrate 11 through utilizing Plasma Enhanced Chemical Vapor Deposition (PECVD) (as shown in FIG. 3B), depositing an intrinsic amorphous silicon layer 13 on the first type amorphous silicon layer 12 (as shown in FIG. 3C), and then depositing a second type amorphous silicon layer 14 on the intrinsic amorphous silicon layer 13 (as shown in FIG. 3D); and finally as shown in step S203 depositing a Group III-V polycrystalline semiconductor layer 15 on the second type amorphous silicon layer 14 (as shown in FIG. 3E) by means of a Metal-Organic Chemical Vapor Deposition (MOCVD).

In the present invention, the lattice characteristics of amorphous silicon layer is used, and the Group III-V polycrystalline semiconductor layer is placed on the amorphous silicon layer, such that the amorphous silicon and the Group III-V material are able to perform photoelectric conversion simultaneously in raising the photoelectric conversion efficiency of a solar cell by means of the direct energy gap of the Group III-V material. In addition, the production cost of solar cell can be properly controlled, so that its cost recovery period is shortened, thus raising it competitiveness on the market.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A Group III-V solar cell, comprising:
a substrate;
a first type amorphous silicon layer, disposed on said substrate;
an intrinsic amorphous silicon layer, disposed on said first type amorphous silicon layer;
a second type amorphous silicon layer, disposed on said intrinsic amorphous silicon layer; and
a Group III-V polycrystalline semiconductor layer, disposed on said second type amorphous silicon layer.

2. The Group III-V solar cell as claimed in claim 1, wherein material of said substrate is selected from a group consisting of: glass, quartz, transparent plastic, sapphire, or flexible materials.

3. The Group III-V solar cell as claimed in claim 1, wherein when said first type amorphous silicon layer is a P-type semiconductor, then said second type amorphous silicon layer is an N-type semiconductor; or when said first type amorphous silicon layer is said N-type semiconductor, then said second type amorphous silicon layer is said P-type semiconductor.

4. The Group III-V solar cell as claimed in claim 3, wherein material of said P-type semiconductor is a transparent conductive oxide selected from a group consisting of: copper aluminum oxide, copper gallium oxide, copper scandium oxide, copper chromium oxide, copper indium oxide, copper yttrium oxide, and silver indium oxide etc.; while material of said N-type semiconductor is said transparent conductive oxide selected from a group consisting of: zinc oxide, tin oxide, indium zinc oxide, and indium tin oxide.

5. The Group III-V solar cell as claimed in claim 1, wherein said Group III-V polycrystalline semiconductor layer is a single junction structure or a multi junction structure, and material of said Group III-V polycrystalline semiconductor layer is selected from a group consisting of: GaAs, GaP, InP, AlGaAs, GaInAs, AlGaP, GaInP AlGaAsP, InGaAsP, AlGaInAsP, or their combinations; or, alternatively, it is selected from a group consisting of: GaN, InN, GaAI, AlGaN, AIInN, AlInGaN, or their combinations.

6. A Group III-V solar cell manufacturing method, comprising the following steps:
providing a substrate;
depositing sequentially a first type amorphous silicon layer, an intrinsic amorphous silicon layer, and a second type amorphous silicon layer on said substrate by means of Plasma Enhanced Chemical Vapor Deposition (PECVD); and
depositing a Group III-V polycrystalline semiconductor layer on said second type amorphous silicon layer by means of a Metal-Organic Chemical Vapor Deposition (MOCVD) through utilizing lattice characteristics of said amorphous silicon layer.

7. The Group III-V solar cell manufacturing method as claimed in claim 6, wherein material of said substrate is selected from a group consisting of: glass, quartz, transparent plastic, sapphire, or flexible materials.

8. The Group III-V solar cell manufacturing method as claimed in claim 6, wherein when said first type amorphous silicon layer is a P-type semiconductor, then said second type amorphous silicon layer is an N-type semiconductor; or when said first type amorphous silicon layer is said N-type semiconductor, then said second type amorphous silicon layer is said P-type semiconductor.

9. The Group III-V solar cell manufacturing method as claimed in claim 8, wherein material of said P-type semiconductor is a transparent conductive oxide selected from a group consisting of: copper aluminum oxide, copper gallium oxide, copper scandium oxide, copper chromium oxide, copper indium oxide, copper yttrium oxide, and silver indium oxide etc.; while material of said N-type semiconductor is said transparent conductive oxide selected from a group consisting of: zinc oxide, tin oxide, indium zinc oxide, and indium tin oxide.

10. The Group III-V solar cell manufacturing method as claimed in claim 6, wherein said Group III-V polycrystalline semiconductor layer is a single junction structure or a multi junction structure, and material of said Group III-V polycrystalline semiconductor layer is selected from a group consisting of: GaAs, GaP, InP, AlGaAs, GaInAs, AlGaP, GaInP, AlGaAsP, InGaAsP, AlGaInAsP, or their combinations; or, alternatively, it is selected from a group consisting of: GaN, InN, GaAl, AlGaN, AlInN, AlInGaN, or their combinations.
